(19) United States
(12) Patent Application Publication
(10) Pub. No.: US 2025/0095970 A1
(43) Pub. Date: Mar. 20, 2025

(54) PLASMA PROCESSING CHAMBER LID COOLING

(71) Applicant: Applied Materials, Inc., Santa Clara, CA (US)

(72) Inventors: Rajinder Dhindsa, Pleasanton, CA (US); Michael Willwerth, Sunnyvale, CA (US); John Poulose, San Jose, CA (US); Kartik Ramaswamy, San Jose, CA (US); Valentin N. Todorow, Palo Alto, CA (US); Mario Schaefer, Altenstadt (DE)

(21) Appl. No.: 18/467,211

(22) Filed: Sep. 14, 2023

(51) Int. Cl. H01J 37/32; H01L 21/67

(52) U.S. Cl. CPC H01J 37/32522; H01J 37/321; H01J 37/32651; H01J 2237/002; H01J 2237/334; H01L 21/67017

(57) ABSTRACT

Semiconductor processing systems and system components are described for mitigating lid heating of a plasma processing chamber. One system includes a plasma-based processing chamber enclosing a processing region, the processing chamber comprising a first portion including sidewalls and a bottom and a second portion including a chamber lid; a substate support within the processing chamber and configured to retain a first substrate in the processing region of the chamber; and a conductive structure proximate to the chamber lid on an exterior side of the processing chamber, the conductive structure forming a particular pattern, the pattern comprising a heat transfer fluid pathway configured to circulate a heat transfer fluid through the conductive structure.

### BACKGROUND

This specification relates to semiconductor systems, processes, and equipment.

Plasma etching can be used in semiconductor processing to fabricate integrated circuits. Integrated circuits can be formed from layer structures including multiple (e.g., two or more) layer compositions. Different etching gas chemistries, e.g., different mixtures of gases, can be used to form a plasma in the processing environment such that a given etching gas chemistry can have increased precision and higher selectivity for a layer composition to be etched.

### SUMMARY

This specification describes technologies for managing temperature of a chamber lid during operation of a plasma processing chamber of a plasma-based processing system. A plasma-based processing system generates a plasma within a processing region to perform a particular process, e.g., plasma etching of a substrate supported within the processing chamber. In an inductively coupled plasma based processing system, the processing chamber has a lid formed from a dielectric material that allows energy from an inductively coupled plasma source to pass through the lid and into the plasma chamber. During a plasma-based processing operation, the lid undergoes heating. In particular, applications that use higher power, for example when performing higher aspect ratio etching operations, increase the amount of lid heating. Excessive heating can lead to damage to the chamber lid.

To reduce lid heating, techniques are provided for introducing a heat transfer fluid in proximity to the chamber lid to provide cooling. In some implementations, heat transfer fluid pathways are formed within a faraday shield structure that is positioned adjacent to the chamber lid. In some implementations, the Faraday shield structure with imbedded fluid pathways is positioned on an exterior (atmosphere side) of the chamber lid. In some other implementations, the Faraday shield structure with imbedded fluid pathways is positioned on an interior (vacuum side) of the chamber lid. Additionally, in some implementations, the fluid pathways are imbedded within the RF inductor coils of the inductively coupled plasma source. In some other implementations, fluid pathways are formed within a block of dielectric material positioned in proximity to an area of the chamber lid.

In general, one innovative aspect of the subject matter described in this specification can be embodied in a system. The system includes a plasma-based processing chamber enclosing a processing region, the processing chamber comprising a first portion including sidewalls and a bottom and a second portion including a chamber lid; a substate support within the processing chamber and configured to retain a first substrate in the processing region of the chamber; and a conductive structure proximate to the chamber lid on an exterior side of the processing chamber, the conductive structure forming a particular pattern, the pattern comprising a heat transfer fluid pathway configured to circulate a heat transfer fluid through the conductive structure.

In general, another innovative aspect of the subject matter described in this specification can be embodied in a system. The system includes a plasma-based processing chamber enclosing a processing region, the processing chamber comprising a first portion including sidewalls and a bottom and a second portion including a chamber lid; a substate support within the processing chamber and configured to retain a first substrate in the processing region of the chamber; an inductively coupled plasma source configured to direct RF energy into the chamber; and a dielectric block proximate to chamber lid on an exterior side of the processing chamber, the dielectric block including a fluid pathway configured to circulate a heat transfer fluid through the fluid pathway of the dielectric block.

In general, another innovative aspect of the subject matter described in this specification can be embodied in a system. The system includes a plasma-based processing chamber enclosing a processing region, the processing chamber comprising a first portion including sidewalls and a bottom and a second portion including a chamber lid; a substate support within the processing chamber and configured to retain a first substrate in the processing region of the chamber; an inductively coupled plasma source configured to direct RF energy into the chamber; and a conductive structure proximate to the chamber lid on an interior side of the processing chamber, the conductive structure comprising a heat transfer fluid pathway configured to circulate a heat transfer fluid through the conductive structure having a particular pattern.

The subject matter described in this specification can be implemented in these and other embodiments so as to realize one or more of the following advantages. The chamber lid heating is managed to maintain a consistent temperature or temperature range that reduces the risk of heat damage to the chamber lid. In particular, the use of fluid pathways adjacent to the chamber lid allows for greater heat mitigation than cooling fans as power levels increase. Increased ability to provide lid cooling allows for higher power etch processes that can provide faster or deeper wafer etching. The embedded heat transfer fluid pathways can additionally supplement cooling provided by cooling fans to improve temperature management of the chamber lid. A Faraday shield for lid heating electronics can be formed with the fluid pathways to provide a combined structure. In some implementations, the fluid pathways are formed within the body of a dielectric material to reduce electromagnetic interference with the source power of the plasma processing chamber. The fluid pathways can be positioned within a structure that is placed within the plasma processing chamber on an interior surface of the chamber lid. This allows for lid temperature management while freeing space on the outside of the processing chamber for other components.

Although the remaining disclosure will describe the innovative technologies in the context of a particular type of plasma-based processing chamber using the disclosed technology, it will be readily understood that the systems and methods may be applicable to a variety of other types of plasma-based substrate processing chambers. Accordingly, the technology should not be considered to be so limited as for use with the described etch-based processing alone. The disclosure will discuss one possible system and chamber that can be used with the present technology before describing systems and methods or operations of exemplary process sequences according to some embodiments of the present technology. It is to be understood that the technology is not limited to the equipment described, and processes discussed can be performed in any number of processing chambers and systems.

### BRIEF DESCRIPTION OF THE DRAWINGS

FIG. 1 shows a schematic cross-sectional view of an example processing chamber.

FIG. 2A shows an isometric view of an example chamber lid and Faraday shield.

FIG. 2B shows an isometric view of another example Faraday shield.

FIG. 3 shows a schematic cross-sectional view of a portion of a processing chamber including the Faraday shield of FIG. 2A.

FIG. 4 shows an isometric view of an example chamber lid and coils.

FIG. 5A shows an isometric view of an example chamber lid and recursive fluid pathways including a dielectric enclosure.

FIG. 5B shows the isometric view of an example chamber lid and recursive fluid pathways of FIG. 5A without a top portion of the dielectric enclosure visible.

FIG. 6 shows an isometric view of an example Faraday shield for performing vacuum-side lid temperature management.

FIG. 7 shows an isometric view of an example Faraday shield for performing vacuum-side lid temperature management coupled to processing chamber sidewalls.

FIG. 8 shows an isometric view of a partial cutaway view of the example Faraday shield of FIG. 7 illustrating imbedded fluid pathways.

FIG. 9 shows a schematic cross-sectional view of a portion of a processing chamber including the Faraday shield of FIG. 6.

FIG. 10 shows an example cross-sectional view of an edge portion of a Faraday shield.

FIG. 11 shows an example cross-sectional view of an edge portion of a Faraday shield.

Like reference numbers and designations in the various drawings indicate like elements.

### DETAILED DESCRIPTION

The present specification describes technologies configured to manage heating of a plasma chamber lid during a plasma processing operation. In some implementations, fluid pathways are combined with a Faraday shield to circulate a heat transfer fluid. The heat transfer fluid can be used to absorb heat energy from the chamber lid to provide cooling. In some other implementations fluid pathways for circulating the heat transfer fluid are combined with one or more inductively coupled plasma source coils. Further, in some implementations, fluid pathways are formed within a block of dielectric material positioned in proximity to the chamber lid.

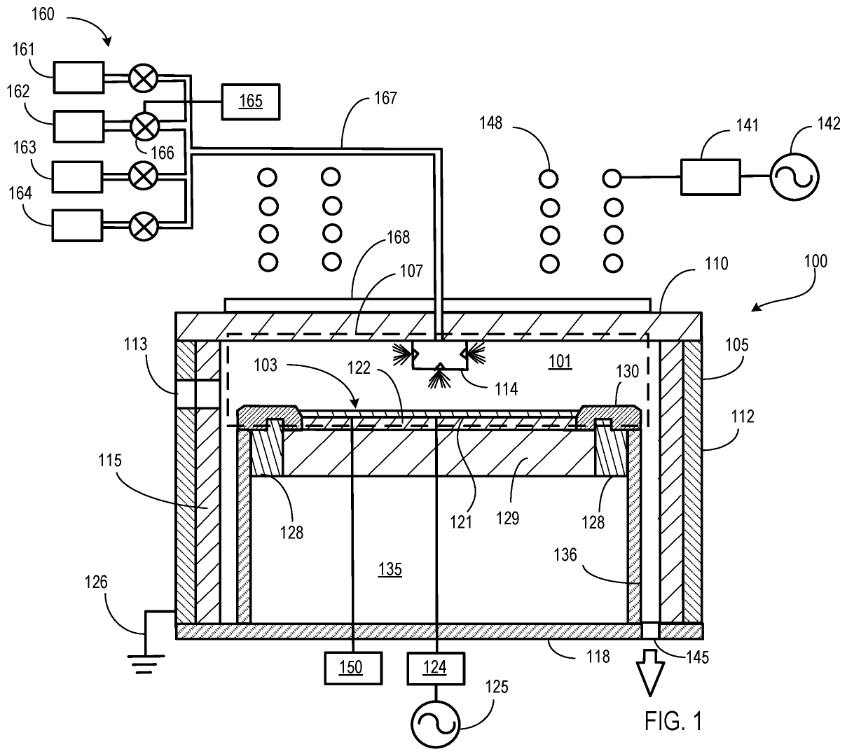

FIG. 1 illustrates a schematic cross-sectional view of an example processing chamber 100 suitable for etching one or more material layer(s) disposed on a substrate 103 (e.g., also referred to as a “wafer”) in the processing chamber 100, e.g., a plasma processing chamber. The processing chamber 100 includes a chamber body 105 defining a chamber volume 101 in which a substrate can be processed. The chamber body 105 has sidewalls 112 and a bottom 118 which are coupled with ground 126. The sidewalls 112 can include a liner 115 to protect the sidewalls 112 and extend the time between maintenance cycles of the plasma processing chamber 100. The chamber body 105 is supportive of a chamber lid 110 to enclose the chamber volume 101. The chamber body 105 can be fabricated from, for example, aluminum or other suitable materials. The chamber lid 110 can be formed from a dielectric material that allows for passage of energy from an inductively coupled plasma (ICP) source through the chamber lid 110 to the processing volume 101. In some instances, the chamber lid 110 is referred to as a dielectric window.

A substrate access port 113 is formed through the sidewall 112 of the chamber body 105, which can facilitate the transfer of the substrate 103 into and out of the plasma processing chamber 100. Access port 113 can be coupled with a transfer chamber and/or other chambers (not shown) of a substrate processing system, e.g., to perform other processes on the substrate. A pumping port 145 is formed through the bottom 118 of the chamber body 105 and connected to the chamber volume 101. A pumping device can be coupled through the pumping port 145 to the chamber volume 101 to evacuate and control the pressure within the processing volume. The pumping device can include one or more vacuum pumps and throttle valves that output gasses and processing byproducts to a foreline vent.

The chamber 100 can also include a lid heater 168 disposed on the outer side of the chamber lid 110 opposite the chamber volume 101. In particular, the lid heater 168 can be positioned between the chamber lid 110 and coils 148 of an inductively coupled plasma source. The lid heater 168 can be used to provide a set chamber temperature before initiating a plasma processing operation. In some implementations, the lid heater 168 includes or is proximate to a shielding material, e.g., Faraday shield, placed between the lid heater 168 and the chamber lid 110. A Faraday shield is a layer of conductive material, e.g., a metal such as aluminum, that blocks electromagnetic energy. The shielding material reduces radio frequency coupling between the ICP source to the lid heater 168. The lid heater 168, with shielding, can be configured into a particular shape with through openings to allow for coupling of the ICP source energy to the chamber volume 101. In particular, without the shielding, the electrically powered heating elements can interact with the electromagnetic field generated by the ICP source coils 148 and passing through the chamber lid 110. The shielding prevents this interaction so that the plasma is accurately formed within the chamber volume 101 to perform plasma processing operations.

In some implementations, the heater 168 includes one or more heating elements, e.g., resistive heating elements, coupled to a power supply (not shown) configured to provide sufficient energy to control the temperature of the heater 168, for example, to be between 50 and 100 degrees Celsius. The heater 168 can be electrically grounded, e.g., to the sidewalls of the chamber 100 or floating, e.g., may be positioned without being electrically coupled to ground. Furthermore, in some other implementations as described below, the lid heater 168 can be a Faraday shield having one or more fluid pathways that circulate a heat transfer fluid. The circulating heat transfer fluid can be used to absorb excess heat from the lid.

Chamber volume 101 includes a processing region 107, e.g., a station for processing a substrate. A substrate support 135 can be disposed in the processing region 107 of chamber volume 101 to support the substrate 103 during processing. The substrate support 135 can include an electrostatic chuck 122 for holding the substrate 103 during processing. The electrostatic chuck (“ESC”) 122 can use the electrostatic attraction to hold the substrate 103 to the substrate support 135. The ESC 122 can be powered by a radio frequency (“RF”) power supply 125 integrated with a match circuit 124. The ESC 122 can include an electrode 121 embedded within a dielectric body. The electrode 121 can be coupled with the RF power supply 125 and can provide a bias which attracts plasma ions, formed from the process gases in the chamber volume 101, to the ESC 122 and substrate 103 seated on the pedestal. The RF power supply 125 can cycle on and off, or pulse, during processing of the substrate 103. The ESC 122 can have an isolator 128 for the purpose of making the sidewall of the ESC 122 less attractive to the plasma to prolong the maintenance life cycle of the ESC 122. Additionally, the substrate support 135 can have a cathode liner 136 to protect the sidewalls of the substrate support 135 from the plasma gases and to extend the time between maintenance of the plasma processing chamber 100.

Electrode 121 can be coupled with a DC power source 150. The power source 150 can provide a chucking voltage of about 200 volts to about 2000 volts to the electrode 121. The power source 150 can also include a system controller for controlling the operation of the electrode 121 by directing a DC current to the electrode 121 for chucking and de-chucking the substrate 103. The ESC 122 can include heaters disposed within the ESC 122 and connected to a power source for heating the substrate, while a cooling base 129 supporting the ESC 122 can include conduits for circulating a heat transfer fluid to maintain a temperature of the ESC 122 and substrate 103 disposed thereon. The ESC 122 can be configured to perform in the temperature range required by the thermal budget of the device being fabricated on the substrate 103. For example, the ESC 122 can be configured to maintain the substrate 103 at a temperature of about −150° C. or lower to about 500° C. or higher depending on the process being performed. A cover ring 130 can be disposed on the ESC 122 and along the periphery of the substrate support 135. The cover ring 130 can be configured to confine etching gases to a desired portion of the exposed top surface of the substrate 103, while shielding the top surface of the substrate support 135 from the plasma environment inside the plasma processing chamber 100.

A gas panel 160 (e.g., also referred to herein as “gas distribution manifold”) can be coupled by a gas line 167 with the chamber body 105 through chamber lid 110 to supply process gases into the chamber volume 101. The gas panel 160 can include one or more process gas sources 161, 162, 163, 164 and can additionally include inert gases, non-reactive gases, and reactive gases, as can be used for any number of suitable processes. Examples of process gases that can be provided by the gas panel 160 include, but are not limited to, hydrocarbon containing gases including methane, sulfur hexafluoride, silicon chloride, silicon tetrachloride, carbon tetrafluoride, hydrogen bromide. Process gases that can be provided by the gas panel can include, but are limited to, argon gas, chlorine gas, nitrogen, helium, or oxygen gas, sulfur dioxide, as well as any number of additional materials. Additionally, process gasses can include nitrogen, chlorine, fluorine, oxygen, or hydrogen containing gases including, for example, BCl₃, C₂F₄, C₄F₈, C₄F₆, CHF₃, CH₂F₂, CH₃F, NF₃, NH₃, CO₂, SO₂, CO, N₂, NO₂, N₂O, and H₂, among any number of additional suitable precursors. Process gases from process gas sources, e.g., sources 161, 162, 163, 164, can be combined to form one or more etching gas mixtures. For example, gas panel 160 includes one or more process gas sources specific to oxide-based etching chemistries. In another example, gas panel 160 includes one or more process gas sources specific to nitride-based etching chemistries.

Gas panel 160 includes various valves and other components to control the flow of the process gases from the sources. Valves 166 can control the flow of the process gases from the gas sources 161, 162, 163, 164 from the gas panel 160. Operations of the valves, pressure regulators, and/or mass flow controllers can be controlled by a controller 165. Controller 165 can be operably coupled to an electro-valve (EV) manifold (not shown) to control actuation of one or more of the valves, pressure regulators, and/or mass flow controllers.

The lid 110 can incorporate a gas delivery nozzle 114. The gas delivery nozzle 114 can include one or more openings for introducing the process gases from the sources 161, 162, 163, 164 of the gas panel 160 into the chamber volume 101. After the process gases are introduced into the plasma processing chamber 100, the gases can be energized to form a plasma. An antenna such as one or more inductor coils 148 can be provided adjacent to the plasma processing chamber 100. An antenna power supply 142 can power the inductor coils 148 through a match circuit 141 to inductively couple energy, such as RF energy, to the process gas to maintain a plasma formed from the process gas in the chamber volume 101 of the plasma processing chamber 100. The operation of the power supply 142 can be controlled by a controller, such as controller 165, that also controls the operation of other components in the plasma processing chamber 100.

The controller 165 can be used to control the process sequence, regulating the gas flows from the gas panel 160 into the plasma processing chamber 100, and other process parameters. Software routines, when executed by a computing device having one or more processors (e.g., a central processing unit (CPU)) in data communication with one or more memory storage devices, transform the computing device into a specific purpose computer such as a controller, which can control the plasma processing chamber 100 such that the processes are performed in accordance with the present disclosure. The software routines can also be stored and/or executed by one or more other controller(s) that can be associated with the plasma processing chamber 100.

In some embodiments, at a termination point of etching process(es) for the wafer, an automatic or semi-automatic robotic manipulator (not shown) can be utilized to transfer the wafer(s) from the substrate support out of the process chamber, e.g., through substrate access port 113. For example, the robotic manipulator can transfer the wafer to another chamber (or another location) to perform another step in a fabrication process.

Although described with respect to FIG. 1 as a process chamber including a substrate support disposed within a processing region of the chamber volume, two or more substrate supports can be disposed within the same chamber volume in respective processing regions, e.g., in respective processing stations. For example, a processing chamber 100 can be a tandem processing chamber including two processing regions each with respective substrate supports configured to retain respective wafers during etching process(es). The processing chamber 100 can include two or more processing regions within the chamber volume 101 to facilitate parallel processing of two or more substrates in respective processing regions. The processing regions can be substantially isolated such that an etching process in a first processing region has minimal effect on an etching process in a second processing region and vice-versa.

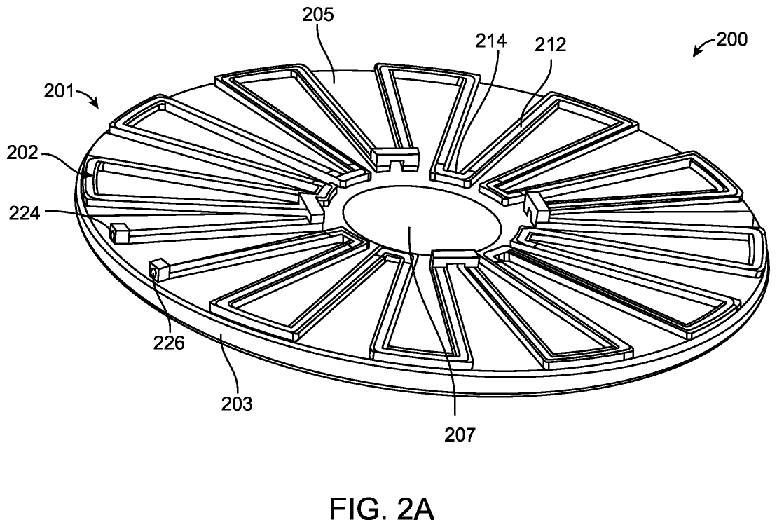

FIG. 2A shows an isometric view 200 of an example chamber lid 201 and Faraday shield 202. The chamber lid 201 can be formed from a single piece of dielectric material. For example, the chamber lid 201 can be formed from Alumina (aluminum oxide Al₂O₃), quartz, or other suitable ceramic materials such as Yttria (Yttria oxide Y₂O₃). The chamber lid 201 can be shaped to form a vacuum seal with sidewalls of the plasma processing chamber during operation. In some implementations, the chamber lid 201 can include a lip edge configured for seating the lid on one or more sidewall edges of the plasma processing chamber.

For example, the chamber lid 201 can be substantially disk shaped, essentially forming a cylinder with a narrow height corresponding to the thickness 203 of the disk and top and bottom circular surfaces. A diameter of the chamber lid 201 can be configured to be set on an end face of a cylindrical sidewalls of the processing region of the plasma processing chamber. The circular surfaces include a vacuum-side surface that faces the inner region of the plasma processing chamber and an atmosphere-side surface 205 that faces away from the plasma processing chamber. In some implementations, the chamber lid need not be disk shaped. For example, the lid can be a rectangular solid or other geometric shape depending on the design of the plasma processing chamber.

The thickness 203 of the disk shaped chamber lid 201 can depend on the material used and the strength needed, for example, to withstand a low pressure plasma environment of the plasma processing chamber.

The chamber lid 201 typically includes an aperture 207 through which a gas delivery nozzle (not shown) is mounted for providing etch gases to the processing chamber. In some other implementations, gas delivery structures may be integrated within the body of the chamber lid 201.

The Faraday shield 202 may have a spoke-like pattern with spokes extending radially around the top surface 205 of the chamber lid 201. The pattern is formed by segments of a switchback path that includes a number of first linear segments, e.g., first segment 212, extending from a first specified radius from a center point of the atmosphere side surface 205 of the chamber lid 201 to a second specified radius from the center point. The switchback path further includes a number of second linear segments, e.g., second segment 214, substantially perpendicular to the radius of the atmosphere-side surface 205 and alternately coupled to first linear segments at the first specified radius and the second specified radius. The Faraday shield is formed from a suitable conductive material, for example, aluminum or copper.

The Faraday shield 202 includes a fluid pathway that extends through the switchback path from an inlet point 208 to an outlet point 210. For example, the switchback path can be formed from a tubular metal material that has an inner diameter defining the fluid pathway. The diameter of the fluid pathway can be selected based on a desired flow rate for a given thermal transfer fluid, e.g., 1 gallon per minute.

To maintain a substantially constant temperature, or a temperature within a specified range, for the chamber lid 201, within the processing chamber, a heat transfer fluid is circulated at a specified temperature though the fluid pathway of within the Faraday shield 202. The heat transfer fluid absorbs heat energy from the chamber lid 201 thereby cooling the chamber lid 201. The heat transfer fluid can be selected according to particular performance parameters such as an ability to operate in particular temperature ranges and chemical stability. The heat transfer fluid can be, for example, a fluorinated fluid such as perfluoropolyether. In some implementations, the heat transfer fluid entering the inlet point 208 is at zero degrees Celsius.

Heat transfer fluid exiting through outlet port 210 can be routed to a heat exchanger or chiller (not shown) to move excess heat before circulating the heat transfer fluid back through the Faraday shield 202. The temperature of the heat transfer fluid entering the input port 208 as well as the flow rate can be controlled to obtain a particular amount of cooling. In particular, heating on the chamber lid 201 may increase during operation of the plasma chamber leading to adjustment of the heat transfer fluid.

The Faraday shield 202 can include one or more heating elements, for example, resistive heating elements that are electrically powered to provide an initial heating of the chamber lid 201, e.g., to 80-90 degrees Celsius. The heating elements can be positioned at particular points along the switchback path of the Faraday shield 202. The heating elements can be coupled to an electrical power source. In some implementations, each heating element is independently controllable.

The lengths of the first and second segments of the switchback path can vary. For example, to place the individual spokes closer together or further apart. Additionally, the radial length of the first segments can vary both for the spokes as a whole as well as for particular individual spokes, e.g., such that some spokes have a longer length than other spokes. The particular geometry of the switchback path can be based on a combination of the geometry needed to provide substantially uniform temperature management of the chamber lid as well as the need for non-conductive pass throughs to the lid to allow the energy of the ICP coils to pass through the chamber lid 201 to the plasma processing chamber.

FIG. 2B shows an isometric view 220 of another example Faraday shield 222. For convenience, the Faraday shield 222 is illustrated with respect to chamber lid 201 corresponding to the chamber lid of FIG. 2A. The Faraday shield 222 illustrates a Faraday shield applied to a smaller region of the chamber lid 201, e.g., a central region, rather than extending for substantially the entire diameter of the chamber lid 201. Similar to the Faraday shield 202 of FIG. 2A, the Faraday shield 222 includes a fluid pathway that extends through the switchback path from an inlet point 224 to an outlet point 226. For example, the switchback path can be formed from a tubular metal material that has an inner diameter defining the fluid pathway. The higher level of heating to the central region of the chamber lid 201 can be managed with a more centrally focused region containing the fluid pathway. The edge region of the chamber lid may be sufficiently cooled, for example, by external cooling fans or thermal conductivity to the center region. The Faraday shield 222 may allow for temperature management using less material than the Faraday shield 202 of FIG. 2A.

Although a switchback path is shown, other geometric patterns of fluid paths can be used as long as the overall structure allows sufficient energy to pass through the conductive structures to form an operating plasma. For example, a zig-zag pattern or an inner ring with outward radiating spokes could be used. Additionally, the fluid pathway can have different cross-sectional geometries including circular and square.

In particular, the heating may be more concentrated at a central region of the chamber lid 201 such that a higher density of cooling pathways are found centrally to provide uniform temperature control of the chamber lid 201.

The Faraday shield 202, 222 can be held in position, and in contact with the atmosphere side surface 205 of the chamber lid 201. For example, an affixing material such as an adhesive can be used to hold the Faraday shield 202, 222 in position on the chamber lid 201. In some other implementations, a force may be applied to the Faraday shield 202, 222 to press the Faraday shield 202, 222 in contact with the chamber lid 201. For example, other components of the processing chamber may be coupled to the Faraday shield 202, 222 to provide a downward pressure toward the lid surface.

In some implementations, a thermally conductive material is placed between the Faraday shield 202, 222 and the chamber lid 201. The thermally conductive material, e.g., a thermal gasket, can help provide a more even distribution of cooling to the chamber lid 201. The thermally conductive material can be, for example, a graphite sheet.

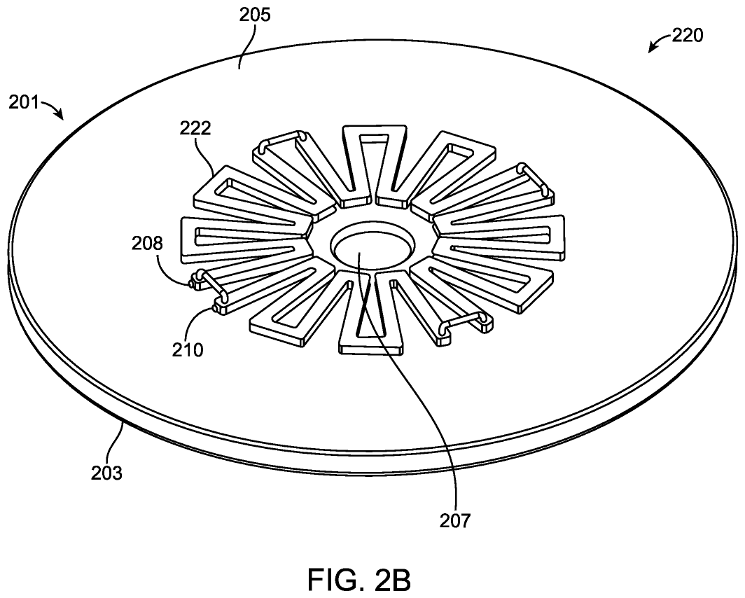

FIG. 3 shows a schematic cross-sectional view 300 of a portion of a processing chamber 301 including the Faraday shield 202 of FIG. 2A. A chamber lid 302 sits upon a lip of sidewalls 304 of the processing chamber 301. A gas distribution nozzle 306 passes through a central aperture of the chamber lid 302 to provide and distribute etch gases into a processing volume 303 of the processing chamber 301. ICP coils 308 are positioned to direct RF energy through the chamber lid 302 and into the processing volume 303. The Faraday shield 202 sits on a surface of the chamber lid 302 and is coupled to a heat transfer fluid input line 310 and a heat transfer fluid output line 312.

In some implementations, the heat transfer fluid can be circulated at a first temperature, e.g., 80 to 90 degrees Celsius, to initially heat the processing chamber or to maintain a temperature between plasma processing operations. The heat transfer fluid can be switched to a heat transfer fluid maintained at a second temperature, e.g., zero degrees Celsius, during a plasma processing operation. Alternatively a single circulating heat transfer fluid can have the temperature adjusted e.g., using a heat exchanger and/or chiller to switch temperatures of the heat transfer fluid. In some such implementations, separate electrical lid heaters are no longer needed. As a result, a Faraday shield may not be needed. The fluid pathways can then be formed of non-conductive materials such as a plastic.

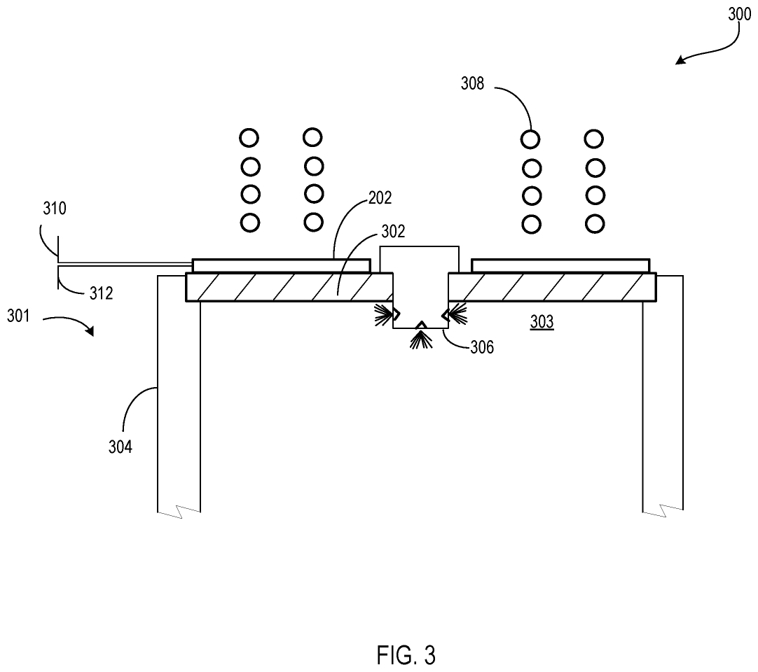

FIG. 4 shows isometric view 400 of an example chamber lid 401, an outer coil 402, and an inner coil 404. The chamber lid 401 can be formed from a single piece of dielectric material. For example, the chamber lid 401 can be formed from Alumina (aluminum oxide Al₂O₃), quartz, or other suitable ceramic materials such as Yttria (Yttria oxide Y₂O₃). The chamber lid 401 can be shaped to form a vacuum seal with sidewalls of the plasma processing chamber during operation. In some implementations, the chamber lid 401 can include a lip edge configured to seat the lid on one or more sidewall edges of the plasma processing chamber.

For example, the chamber lid 401 can be substantially disk shaped, essentially forming a cylinder with a narrow height corresponding to the thickness 403 of the disk and top and bottom circular surfaces. A diameter of the chamber lid 401 can be configured to be seated on an end face of a cylindrical sidewalls of the processing region of the plasma processing chamber. The circular surfaces include a vacuum side surface that faces the inner region of the plasma processing chamber and an atmosphere side surface 405 that faces away from the plasma processing chamber.

The thickness 403 of the disk shaped chamber lid 401 can depend on the material used and the strength needed, for example, to withstand a low pressure plasma environment of the plasma processing chamber.

The chamber lid 401 includes an aperture 407 through which a gas delivery nozzle (not shown) is mounted for providing etch gases to the processing chamber. In some other implementations, gas delivery structures may be integrated within the body of the chamber lid 401.

Each of outer coil 402 and inner coil 404 contain an interior fluid pathway for circulating a heat transfer fluid. The outer coil 402 is shown as a three row flat coil, or spiral, encircling an outer region of the chamber lid 401. The outermost portion of the outer coil 402 is in proximity to the outer edge of the atmosphere side surface 405. The innermost portion of the outer coil 402 is a specified radial distance from a center point of the chamber lid 401. The outer coil 402 includes an input port 406 allowing the heat transfer fluid to enter the fluid pathway of the outer coil 402 and an output port 408 allowing the heat transfer fluid to exit the fluid pathway of the outer coil 402. Each row of the outer coil 402 has a specified separation from adjacent row or rows of the coil.

The inner coil 406 is shown as a three row flat coil, or spiral, encircling an inner region of the chamber lid 401. The innermost portion of the inner coil 404 is a specified radial distance from a center point of the chamber lid 401. The outermost portion of the inner coil 404 is a specified radial distance from the innermost portion of the outer coil 406. Thus, there is a separation between the inner coil 406 and the outer coil 404. The inner coil 404 includes an input port 410 allowing the heat transfer fluid to enter the fluid pathway of the outer coil 402 and an output port 412 allowing the heat transfer fluid to exit the fluid pathway of the outer coil 402. Each row of the inner coil 404 has a specified separation from adjacent row or rows of the coil.

Each of the inner coil 406 and the outer coil 404 have a thermally conductive material, 414, 416, positioned between the respective coils and the chamber lid 401. The thermally conductive material, such as a graphite sheet, has a high thermal conductivity to more evenly distribute the lid cooling. In some implementations, only one or neither coil includes the thermally conductive material.

The inner coil 406 and the outer coil 404 can be made from a thermally conductive material as well as an electrically conductive material, e.g., copper or other suitable metal. In particular, in some implementations, the coils also act as a Faraday shield and can include one or more shielded electric heating units.

The number of coils and the number of rows or windings in each coil can vary depending on the application and cooling specified. For example, the inner coil 404 can include additional windings to provide greater cooling to the center region of the chamber lid, which is where the greatest amount of lid heating occurs during a plasma processing operation. Similarly, the spacing between each winding can vary depending on the amount of cooling needed and the ability to transfer RF energy into the processing chamber.

The fluid pathways formed within each coil can have various cross-sectional geometries including circular, rectangular, or other polygonal cross-sections. The cross-sectional diameter can depend on the heat transfer fluid properties and the specified flow rate to provide suitable heat transfer. The heat transfer fluid absorbs heat energy from the chamber lid 401 thereby cooling the chamber lid 401. For example, the heat transfer fluid can be ethylene glycol at one gallon per minute flow rate.

There can be a separate cooling loop for each of the inner coil 406 and the outer coil 404. Heat transfer fluid exiting through each outlet port can be routed to a respective heat exchanger or chiller (not shown) to move excess heat before circulating the heat transfer fluid back through the corresponding coil.

In some implementations, one or more of the coils also function as the ICP coils for a plasma processing system. Thus, instead of a vertical coil positioned above the lid, e.g., coils 148 shown in FIG. 1, one or more flat coils as shown in FIG. 4 can be powered by a power source to generate RF energy into the processing chamber. Thus, the heat transfer fluid can flow within an interior pathway of the coil while the coil is powered to generate RF energy for the plasma chamber. In some instances just the inner coil 404 operates as the ICP coil while the outer coil 402 is solely for cooling. In some other cases, the reverse. And in further other implementations, both coils are powered. In some implementations, an interior surface of the interior pathway is coated with an insulating material.

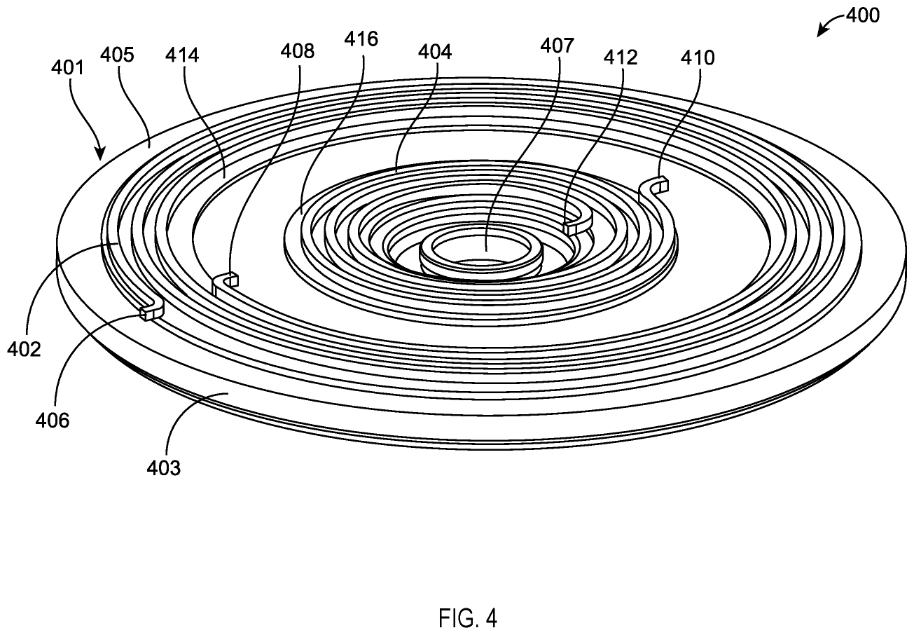

FIG. 5A shows an isometric view 500 of an example chamber lid 502 and recursive fluid pathway including a dielectric enclosure. FIG. 5B shows the isometric view 501 of the example chamber lid 502 and recursive fluid pathway of FIG. 5A without a top portion of the dielectric enclosure visible.

The chamber lid 502 can be similar to the chamber lid 401 described with respect to FIG. 4. A recursive cooling pathway 504 is positioned in a center region of the atmosphere side surface of the chamber lid 502. The recursive fluid pathway 504 includes an input port 508 and an output port 510 for circulating a heat transfer fluid through the recursive fluid pathway 504.

The recursive fluid pathway 504 is positioned within an enclosure 506 having a portion between the surface of the chamber lid 502 and the recursive fluid pathway 504 and a cover portion 512 that encloses the other side of the recursive fluid pathway 504. The enclosure 506 can be formed from a dielectric material such as aluminum nitride or other suitable ceramic material. In particular, the enclosure 506 is formed from a material with suitable thermal conductance to sufficiently transfer heat from the chamber lid 502. As a dielectric material, it does not block RF energy from an ICP power source. The enclosure 506 can have a disk shape with a center aperture that allows for the positioning of the gas delivery nozzle and other central components of the plasma processing system.

In contrast to FIG. 4, the fluid pathway 504 is only located in a central region of the chamber lid 401 because the greatest amount of cooling is needed in the central region. However, the recursive fluid pathway can extend with additional loops to cover a larger portion of the surface of the chamber lid 502. Alternatively, a separate recursive loop can be used in an outer region similar to the inner and outer coils shown in FIG. 4.

In some implementations, the fluid pathway 504 is formed within the body of a solid enclosure made from a dielectric material. For example, a first layer of dielectric material, such as aluminum nitride or other ceramic material, can be milled to form a lower half of the fluid pathway in a surface of the first layer a second layer can be machined to form a mirrored upper half of the fluid pathway in a surface of the second layer. These layers can be then joined together to form the fluid pathway 504, e.g., using an adhesive and sealants as suitable. In another example, additive manufacturing techniques can be used to build up the enclosure 506 layer by layer of aluminum nitride or other ceramic material. In 3D printing the layers using additive manufacturing, the fluid pathway 504 can be formed and enclosed within the enclosure 506 as a single component.

In some other implementations, the enclosure is formed from separate pieces of dielectric material that surround a fluid pathway 504. The recursive fluid pathway 504 can be formed from a metallic material such as copper or aluminum. Alternatively, the fluid pathway 504 can be formed from a non-conductive material such as a plastic. The thermal transfer fluid can be any suitable thermal transfer fluid such as perfluoropolyether or ethylene glycol as described above. The thermal transfer fluid can be selected and the recursive fluid pathway defined, e.g., cross-sectional diameter, to achieve a specified flow rate through the recursive cooling pathway to provide a particular amount of heat transfer. For example, the recursive fluid pathway 504 can be configured to circulate the thermal transfer fluid at a flow rate of one gallon per minute at a specified temperature, e.g., zero degrees Celsius.

The chamber lids of FIGS. 4-5, may further include one or more lid heaters. The lid heaters can be used, for example, to provide an initial baseline temperature for the processing chamber. In some other implementations, the heat transfer fluid is used to provide both heating and cooling the chamber lid. In implementations having lid heaters, the lid heaters can be shielded, e.g., with a Faraday shield, to prevent interference with the RF source power.

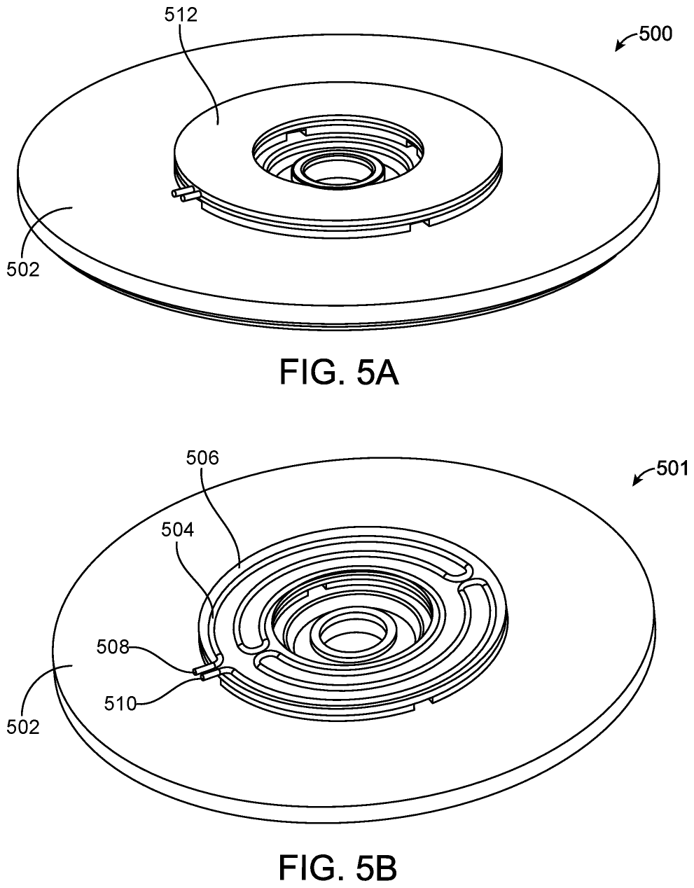

FIG. 6 shows an isometric view 600 of an example Faraday shield 602 for performing vacuum-side lid temperature management. In contrast to the Faraday shields shown in FIGS. 2-5, the Faraday shield 602 is configured to be positioned on an interior surface of the chamber lid within the processing volume of a plasma processing chamber. The Faraday shield 602 includes an annular portion 604 and a spoke portion 606.

The annular portion 604 is configured such that the Faraday shield 602 can be coupled to the sidewalls of a plasma processing chamber. The spoke portion 606 includes multiple individual spokes that extend radially inward from the annular portion 604. As shown in FIG. 6, the spokes have different lengths and do not extend completely to a central region. The annular portion 604 and each spoke of the spoke portion 606 have a width and height configured to provide a fluid pathway 608 within the annular portion and each spoke while having sufficient strength to remain rigid within a low pressure plasma environment. In some implementations, the Faraday shield 602 is further configured to provide structural support for the chamber lid of the plasma processing chamber.

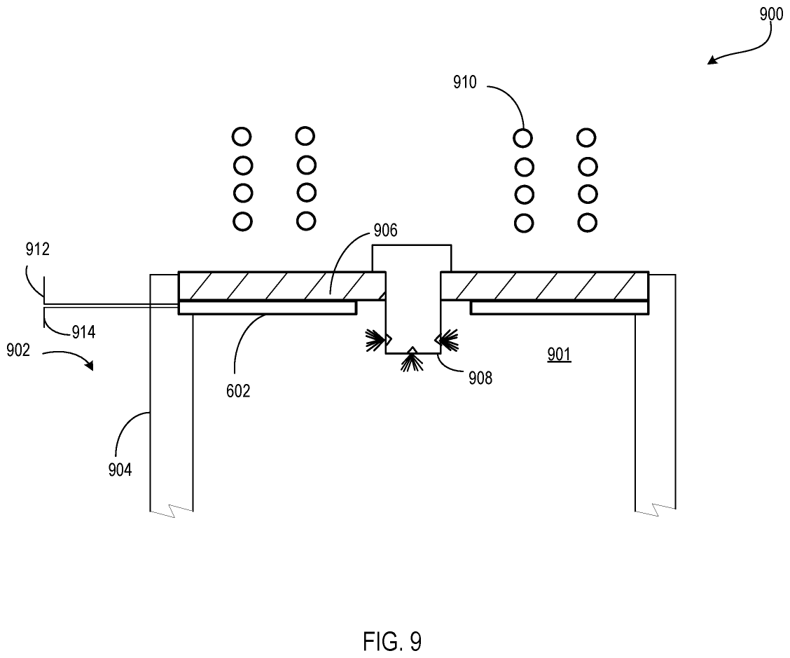

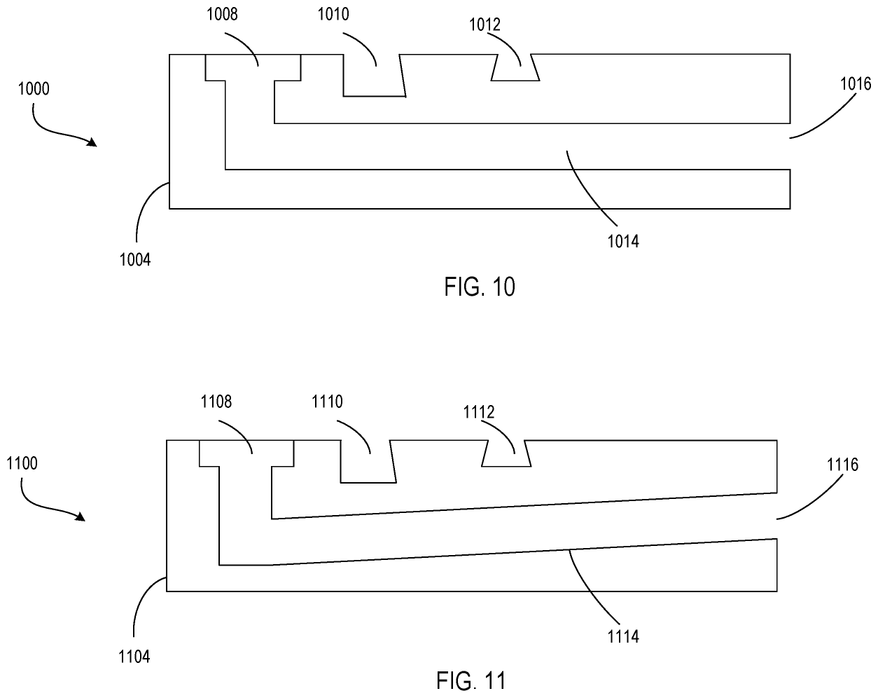

In FIG. 6, the fluid channel 608 is exposed for illustration though in a completed Faraday shield 602 the fluid channel would be fully encapsulated by the material of the Faraday shield 602. The fluid channel 608 begins at a side input port 610 of the Faraday shield 602 (illustrated in FIGS. 10-11) and follows a path along the annular portion 604 to a first spoke in the spoke portion 606. The fluid pathway 608 passes along one side of the spoke toward the center of the Faraday shield 602 and back down a second side of the spoke. The fluid pathway 608 then is formed in the annular portion 606 until the next spoke is reached where the path repeats for each spoke until a side output port 612.

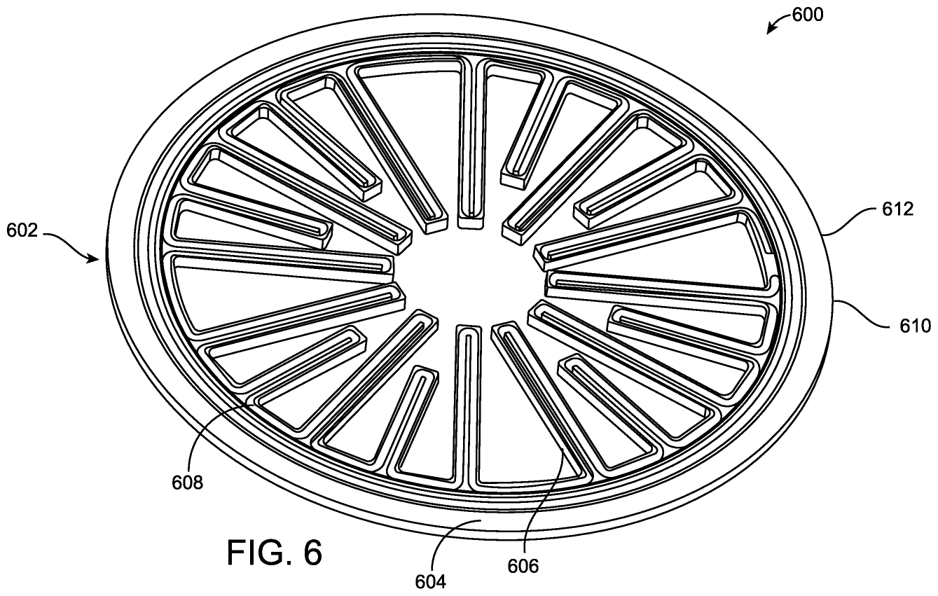

FIG. 7 shows an isometric view of the example Faraday shield 602 for performing vacuum-side lid temperature management coupled to processing chamber sidewalls 702. In particular, FIG. 7 shows the annular portion 604 of the Faraday shield 602 coupled to the processing chamber sidewalls 702. The chamber lid can be seated on top of the Faraday shield 602 to enclose the processing volume of the processing chamber with the Faraday shield 602 on the interior side of the chamber lid. In some implementations, the height of the processing chamber sidewalls 702 have been adjusted, e.g., shortened by the height of the Faraday shield 602, so that the distance between lid and the substrate in the processing chamber is the same as in the processing chamber shown in FIG. 2.

A heat transfer fluid, such as described above with respect to FIG. 2, is circulated through the fluid pathway 608 from the input port 610 to an output port 612 to provide cooling to the chamber lid during a plasma processing operation in which the Faraday shield 602 is in contact with a surface of the chamber lid. In particular, the Faraday shield 602 is in direct physical contact with portions of the chamber lid to provide a transfer of heat energy from the lid to the heat transfer fluid.

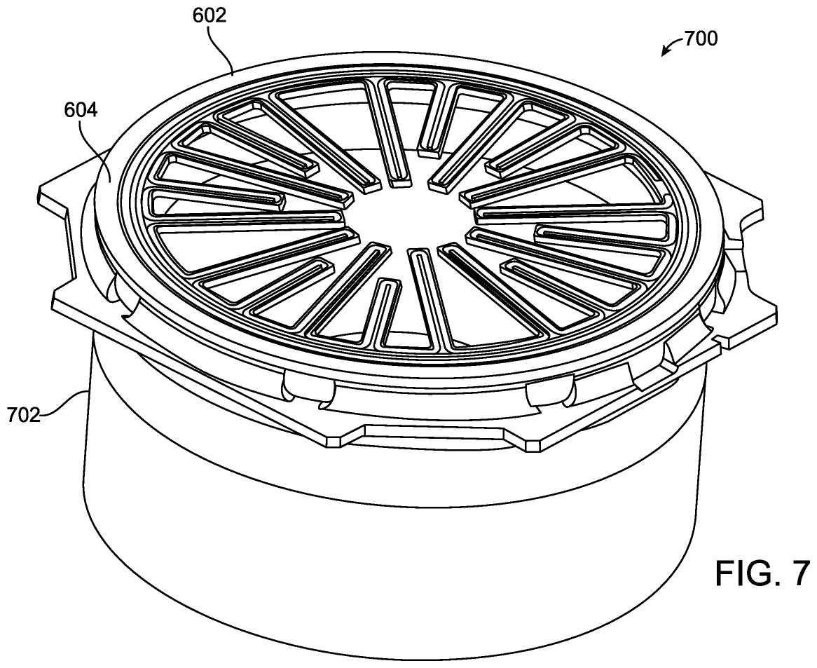

FIG. 8 shows an isometric view of a partial cutaway view 800 of the example Faraday shield 602 of FIG. 6 illustrating imbedded fluid pathways. The partial cutaway view 800 illustrates a portion of the annular ring and spokes of the Faraday shield 602. A fluid pathway 802 is illustrated for clarity but would be encapsulated in the final Faraday shield structure. Additionally, the partial cutaway view 800 illustrates two additional ring channels in the annular portion of the Faraday shield 602. The ring channels provide for particular sealing rings. The first ring channel 806 provides structural support for an RF gasket that creates an RF barrier. The second ring channel 804 provides structural support for a sealing gasket, e.g., an O-ring, that protects the vacuum environment within the processing chamber by forming a seal between the Faraday shield 602 and the chamber lid.

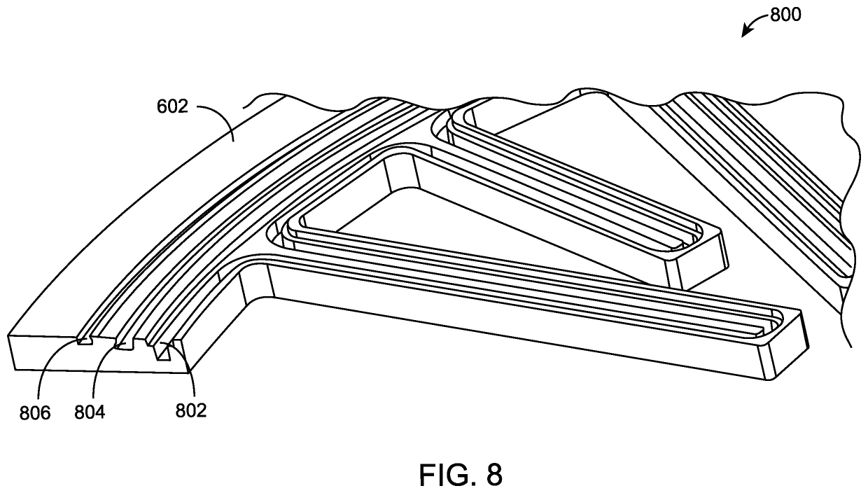

FIG. 9 shows a schematic cross-sectional view 900 of a portion of a processing chamber 902 including the Faraday shield 602 of FIG. 6. The Faraday shield 602 sits upon a lip of sidewalls 904 of the processing chamber 902. A chamber lid 906 sits upon the Faraday shield 602. A gas distribution nozzle 908 passes through a central aperture of the chamber lid 906 to provide and distribute etch gases into a processing volume 901 of the processing chamber 902. In particular, the gas distribution nozzle 908 passes beyond the Faraday shield 602 into the processing chamber 902. ICP coils 910 are positioned to direct RF energy through the chamber lid 906 and into the processing volume 901. The Faraday shield 602 is coupled to a heat transfer fluid input line 912 and a heat transfer fluid output line 914.

FIG. 10 shows an example cross-sectional view 1000 of an edge portion of a Faraday shield 1002. In particular, FIG. 10 illustrates a cross-section of an annular portion 1004 of the Faraday shield 1002 located at an input port 1016 of the heat transfer fluid pathway 1008. The cross sectional view 1000 includes the first ring channel 1012 for an RF seal and a second ring channel 1010 for a vacuum seal, e.g., an O-ring. A horizontal pathway 1014 couples the heat transfer fluid between the heat transfer fluid pathway 1008 and the input port 1016.

As shown in FIG. 10, the spacing between the ring channels 1010, 1012 and the horizontal pathway 1014 is narrow and in some instances could put additional stress on the structure. An alternative structure is illustrated in FIG. 11.

FIG. 11 shows an example cross-sectional view 1100 of an edge portion of a Faraday shield 1102. In particular, FIG. 11 illustrates a cross-section of an annular portion 1104 of the Faraday shield 1102 located at an input port 1116 of the heat transfer fluid pathway 1108. The cross sectional view 1100 includes the first ring channel 1112 for an RF seal and a second ring channel 1110 for a vacuum seal, e.g., an O-ring. In FIG. 11, a slanted pathway 1114 couples the heat transfer fluid between the heat transfer fluid pathway 1108 and the input port 1116. The slanted pathway 1114 is angled relative to a plane of the Faraday shield 1102. This can provide for a greater separation between the slanted pathway 1114 and the ring channels to provide additional structural support to the Faraday shield 1102.

While this specification contains many specific implementation details, these should not be construed as limitations on the scope of what is being claimed, which is defined by the claims themselves, but rather as descriptions of features that can be specific to particular embodiments of particular inventions. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features can be described above as acting in certain combinations and even initially be claimed as such, one or more features from a claimed combination can in some cases be excised from the combination, and the claim can be directed to a subcombination or variation of a subcombination.

Similarly, while operations are depicted in the drawings and recited in the claims in a particular order, this by itself should not be understood as requiring that such operations be performed in the particular order shown or in sequential order, or that all illustrated operations be performed, to achieve desirable results. In certain circumstances, multitasking and parallel processing can be advantageous. Moreover, the separation of various system modules and components in the embodiments described above should not be understood as requiring such separation in all embodiments, and it should be understood that the described program components and systems can generally be integrated together in a single software product or packaged into multiple software products.

Particular embodiments of the subject matter have been described. Other embodiments are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing can be advantageous.

What is claimed is:

1. A system comprising:
a plasma-based processing chamber enclosing a processing region, the processing chamber comprising a first portion including sidewalls and a bottom and a second portion including a chamber lid;
a substate support within the processing chamber and configured to retain a first substrate in the processing region of the chamber; and
a conductive structure proximate to the chamber lid on an exterior side of the processing chamber, the conductive structure forming a particular pattern, the pattern comprising a heat transfer fluid pathway configured to circulate a heat transfer fluid through the conductive structure.

2. The system of claim 1, wherein the conductive structure is a tubular pathway forming a fluid pathway that is shaped in a switchback path that traverses around a surface of the chamber lid.

3. The system of claim 2, wherein the conductive structure has a diameter that is less than a chamber lid diameter such that the conductive structure only overlaps a central region of the chamber lid.

4. The system of claim 1, wherein the conductive structure is a flat coil having the fluid pathway formed within the body of the flat coil.

5. The system of claim 1, wherein the conductive structure comprises a first flat coil and a second flat coil, each flat coil having the fluid pathway formed within the body of the respective first and second flat coil, the first flat coil being inset within the second flat coil and separated by a specified distance.

6. The system of claim 1, wherein the conductive structure further comprises one or more electronic heaters and, wherein the conductive structure operates as a Faraday shield.

7. The system of claim 1, further comprising a thermally conductive material positioned between the conductive structure and the chamber lid.

8. The system of claim 1, wherein the conductive structure is a flat coil having the fluid pathway formed within the body of the flat coil, and wherein the conductive structure is electrically coupled to a power source such that, when powered, the flat coil passes radio frequency energy into the processing region of the processing chamber.

9. A system comprising:
a plasma-based processing chamber enclosing a processing region, the processing chamber comprising a first portion including sidewalls and a bottom and a second portion including a chamber lid;
a substate support within the processing chamber and configured to retain a first substrate in the processing region of the chamber;
an inductively coupled plasma source configured to direct RF energy into the chamber; and
a dielectric block proximate to chamber lid on an exterior side of the processing chamber, the dielectric block including a fluid pathway configured to circulate a heat transfer fluid through the fluid pathway of the dielectric block.

10. The system of claim 9, wherein the fluid pathway is a recursive path enclosed within the dielectric block.

11. The system of claim 9, wherein the dielectric block covers a central region of the chamber lid.

12. The system of claim 9, wherein the dielectric block and the fluid pathway are formed through additive manufacturing.

13. The system of claim 9, wherein the dielectric block conducts the thermal transfer of heat from the chamber lid to the circulating heat transfer fluid.

14. A system comprising:
a plasma-based processing chamber enclosing a processing region, the processing chamber comprising a first portion including sidewalls and a bottom and a second portion including a chamber lid;
a substate support within the processing chamber and configured to retain a first substrate in the processing region of the chamber;
an inductively coupled plasma source configured to direct RF energy into the chamber; and
a conductive structure proximate to the chamber lid on an interior side of the processing chamber, the conductive structure comprising a heat transfer fluid pathway configured to circulate a heat transfer fluid through the conductive structure having a particular pattern.

15. The system of claim 14, wherein the conductive structure comprises an annular portion and a spoke portion comprising multiple individual spokes that extend radially inward from the annular portion.

16. The system of claim 15, wherein the-annular portion is configured to be coupled to the sidewalls of the processing chamber.

17. The system of claim 16, wherein the chamber lid is positioned to enclose the processing chamber and when positioned the chamber lid is in physical contact with the conductive structure.

18. The system of claim 14, wherein the fluid pathway begins at a side input port of the conductive structure and follows a path along the annular portion to a first spoke in the spoke portion, the fluid pathway passes along one side of the first spoke toward the center of the conductive structure and back down a second side of the first spoke, the fluid pathway then is formed in the annular portion until the second spoke is reached, wherein the fluid path repeats for each spoke until ending at a side output port.

19. The system of claim 14, wherein the annular portion includes an inlet port and an outlet ports, wherein the inlet port and outlet port are coupled to the fluid pathway allowing the heat transfer fluid to circulate through the fluid pathway.

20. The system of claim 19, wherein the fluid pathway is coupled to the inlet port through the annular portion by an angled path relative to a plane of the conductive structure.
